(19) United States
(12) Patent Application Publication
(10) Pub. No.: US 2015/0334852 A1
(43) Pub. Date: Nov. 19, 2015

(54) Packaging Box for an Electronic Device

(71) Applicants: BOE TECHNOLOGY GROUP CO., LTD., Beijing (CN); BOE (Hebei) Mobile Display Technology Co., LTD., Gu'An (CN)

(72) Inventors: Guowen YANG, Beijing (CN); Dongnian HAN, Beijing (CN); Yu QIN, Beijing (CN); Xing LI, Beijing (CN)

(21) Appl. No.: 14/500,322

(22) Filed: Sep. 29, 2014

(30) Foreign Application Priority Data
May 14, 2014 (CN) 201420245818.5

(51) Int. Cl. H05K 5/00; H05K 5/02; H05K 5/03

(52) U.S. Cl. CPC H05K 5/0004; H05K 5/0017; H05K 5/03; H05K 5/0226; H05K 5/0221

(57) ABSTRACT

The invention discloses a packaging box for an electronic device, wherein an opening is formed in one surface of a box body of the packaging box, and a detachable cover plate is mounted on the opening; the remaining part of the box body is composed of box plates with an integrated groove-shaped structure; the electronic device is placed in the box body, and an input-output and control module connected with the electronic device is arranged on the cover plate. According to the packaging box for an electronic device disclosed by the invention, by arranging the detachable cover plate on the opening in the one surface of the box body of the packaging box, and forming the remaining part into the integrated groove-shaped structure, the box body has better overall sealing performance, and moreover, disassembling one cover plate can reduce the workload of disassembly and assembly.

### FIELD OF THE INVENTION

The present invention relates to a packaging structure for an electronic device, and particularly relates to a packaging box for an electronic device, which is convenient to disassemble and assemble and is fixed without screw.

### BACKGROUND OF THE INVENTION

Most of electronic devices are integrated in packaging boxes presently, so as to facilitate safe use and position changeover for the electronic devices. In an existing packaging box, housing is fixed by screws, so that there are many fixing points and many screws are used, and disassembling and assembling the housing of the device is time consuming and labour intensive, thus bringing great inconvenience to assembly and maintenance.

### SUMMARY OF THE INVENTION

(1) Technical problem to be solved The technical problem to be solved by the present invention is how to simplify disassembly and assembly of a packaging box for an electronic device.

(2) Technical solution

In order to solve the above technical problem, the present invention provides a packaging box for an electronic device, wherein an opening is formed in one surface of a box body of the packaging box, and a detachable cover plate is mounted on the opening; the remaining part of the box body is composed of box plates with an integrated groove-shaped structure; the electronic device is placed inside the box body, and an input-output and control module connected with the electronic device is arranged on the cover plate.

Preferably, a signal interface is formed in the box plates with the integrated groove-shaped structure, and the electronic device is connected with an external device through the signal interface.

Preferably, the input-output and control module comprises a liquid crystal touch screen.

Preferably, the input-output and control module comprises a display screen and a keyboard.

Preferably, one side of the cover plate is connected with the box plates with the integrated groove-shaped structure at the opening by means of a hinge, and the other side of the cover plate, opposite to said one side, is connected with the box plates with the integrated groove-shaped structure at the opening by means of a lockset.

Preferably, the box plates with the integrated groove-shaped structure are integrally moulded or formed by hermetically welding the box plates of respective surfaces.

Preferably, the input-output and control module is connected with the electronic device by means of a flexible flat cable.

Preferably, a movable support is further arranged at the bottom of the packaging box, the packaging box is placed on the movable support, and an inclination angle of a support surface of the movable support is adjustable.

(3) Beneficial effects

The above technical solution has the following advantages: by arranging the detachable cover plate on the opening in one surface of the box body of the packaging box, and forming the remaining part into the integrated groove-shaped structure, the box body has better overall sealing performance, and moreover, disassembly of only one cover plate can reduce the workload of disassembly and assembly, thus the packaging box for an electronic device is more convenient to assemble and disassemble.

### BRIEF DESCRIPTION OF THE DRAWINGS

FIG. 1 is a schematic diagram of an overall structure of a packaging box for an electronic device of an embodiments of the present invention; and

FIGS. 2 to 4 are schematic diagrams of structures of various separate components of the packaging box for an electronic device in FIG. 1.

In these figures, 1: box body; 2: cover plate; 3: display screen; 4: keyboard; 5: signal interface.

### DETAILED DESCRIPTION OF THE EMBODIMENTS

The specific implementations of the present invention will be further described below in detail in combination with the accompanying drawings and embodiments. The embodiments below are used for illustrating the present invention, rather than limiting the scope of the present invention.

In the descriptions of the present invention, it should be noted that, the orientations or position relationships indicated by the terms “front”, “rear”, “top”, “bottom”, “interior”, “exterior” and the like are based on orientations or position relationships shown in the accompanying drawings, merely used for facilitating description of the present invention and simplifying the description instead of indicating or implying that the specified device or component must have a specific orientation, and must be constructed and operated in a specific orientation, and therefore, cannot be understood as the limitations on the present invention.

In the descriptions of the present invention, it should be noted that, unless otherwise specified and defined, the terms “assembly”, “interconnection” and “connection” should be generally understood, for example, connection may be fixed connection or detachable connection or integrated connection; connection may also be mechanical connection or electric connection; and interconnection may be direct interconnection, indirect interconnection using an intermediate agent or interior communication between two components. For a person of ordinary skill in the art, the specific meanings of the above terms in the present invention can be understood according to specific conditions.

In addition, in the description of the present invention, unless otherwise illustrated, “a plurality of” and “a plurality of” groups of mean two or more.

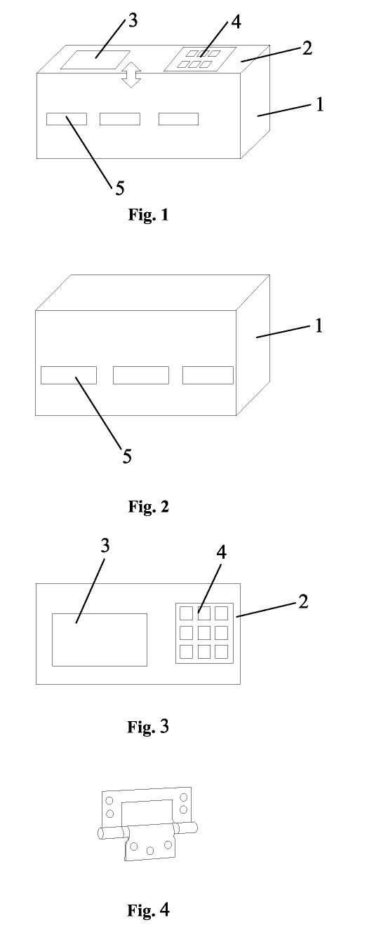

In order to simplify disassembly and assembly of a packaging box for an electronic device, the present invention provides a packaging box for an electronic device, referring to FIG. 1, an opening is provided in one surface of a box body 1 of the packaging box, that is, the opening is provided in the top surface of the box body 1 shown in FIG. 1, and a detachable cover plate 2 is mounted on the opening; the remaining five surfaces of the box body 1 form an integrated groove-shaped structure, that is, the bottom surface and the four side surfaces of the box body 1 form the integrated groove-shaped structure and are composed of box plates with an integrated groove-shaped structure; an electronic device is placed inside the box body 1, and an input-output and control module connected with the electronic device is arranged on the cover plate 2.

Preferably, as shown in FIG. 2, a signal interface 5 is formed in the side surface of the box plates with the integrated groove-shaped structure, and the electronic device inside the box body 1 is connected with an external device through the signal interface 5; and the position of the signal interface 5 is correspondingly arranged according to different installation positions of an electronic device circuit board, and a signal interface 5 may be provided in any side surface of the box plates.

As shown in FIG. 3, the input-output and control module may be configured to be a display screen 3 and a keyboard 4, and the display screen 3 and the keyboard 4 are embedded in the cover plate 2, thus the whole box body is beautiful in appearance, and external operation control on the electronic device is facilitated; or, the input-output and control module is directly configured to be a liquid crystal touch screen integrating the functions of the display screen 3 and the keyboard 4, and capable of carrying out both result display and operation control on the working state of the electronic device; and the input-output and control module is connected with the electronic device by means of a flexible flat cable, which can facilitate the opening-closing operation of the cover plate 2.

A fixed hole site for installing the circuit board is formed on the bottom inside the box body 1, so as to realize the stability and firmness of the circuit board inside the box body 1, thus avoiding random movement; one side of the cover plate 2 is connected with the box plates with the integrated groove-shaped structure at the opening by means of a hinge (referring to FIG. 4), the other side of the cover plate 2, opposite to said one side, is connected with the box plates with the integrated groove-shaped structure at the opening by means of a lockset, the connection using the hinge can reduce the quantity of the screws used during assembly of the box body, simplify disassembly and assembly of the box body, and save time; and as for the connection using the lockset, a special key may be set, the special key is needed when the cover plate 2 is opened or closed to guarantee safety, so that a non-professional personnel cannot disassemble the device privately.

The box plates of both the bottom surface and the surrounding side surfaces of the box body are configured to be in an integrated structure, thus the sealing effect is good, damages to the electronic device due to water vapour erosion are avoided, no screw is needed for connection and fixing, and assembly is very convenient, and the box plates of both the bottom surface and the surrounding side surfaces of the box body may be integrally moulded by a special mould or may be formed by hermetically welding the box plates of the respective surfaces. A movable support is further arranged at the bottom of the packaging box, the packaging box is placed on the movable support, and the inclination angle of the support surface of the movable support is adjustable, thus the angle at which the device is placed is adjustable, which facilitates operation.

Obviously, the packaging box for an electronic device of the present embodiment is not limited to the structure shown in FIG. 1, a box plate of a side surface of the box body may be configured to be the cover plate, in which the input-output and control module is embedded, according to the different use environments of the packaging box, thus facilitating the operations of the electronic device by operating personnel; further, the shape of the box body is not completely limited to a cuboid shape, and may be configured to be a corresponding polyhedron as needed.

In the above packaging box with the electronic device installed therein, when the electronic device works normally, the cover plate is closed, and the cover plate and the box body are locked by the lockset; and when the electronic device needs to be debugged or maintained, the lock is unlocked, and then the cover plate is opened to debug or maintain the electronic device.

It can be seen from the above embodiments that, no screw for connection is used in the box plates with the integrated groove-shaped structure (except the cover plate) of the packaging box of the present invention, and screws are only used at the junction of the hinge, in this way, assembly of the packaging box is quite convenient, the circuit board inside the box body can be operated only by opening the cover plate when the device needs to be maintained, and the whole packaging box is convenient to disassemble and assemble, and simple to operate.

The foregoing descriptions are merely preferred implementations of the present invention, it should be noted that, for the person of ordinary skill in the art, many improvements and substitutions can also be made without departing from the technical principle of the present invention, and these improvements and substitutions should be regarded as the protection scope of the present invention.

1. A packaging box for an electronic device, wherein an opening is formed in one surface of a box body of the packaging box, and a detachable cover plate is mounted on the opening; the remaining part of the box body is composed of box plates with an integrated groove-shaped structure; the electronic device is placed inside the box body, and an input-output and control module connected with the electronic device is arranged on the cover plate.

2. The packaging box for an electronic device according to claim 1, wherein a signal interface is formed in the box plates with the integrated groove-shaped structure, and the electronic device is connected with an external device through the signal interface.

3. The packaging box for an electronic device according to claim 1, wherein the input-output and control module comprises a liquid crystal touch screen.

4. The packaging box for an electronic device according to claim 1, wherein the input-output and control module comprises a display screen and a keyboard.

5. The packaging box for an electronic device according to claim 1, wherein one side of the cover plate is connected with the box plates with the integrated groove-shaped structure at the opening by means of a hinge, and the other side of the cover plate, opposite to said one side, is connected with the box plates with the integrated groove-shaped structure at the opening by means of a lockset.

6. The packaging box for an electronic device according to claim 1, wherein the box plates with the integrated groove-shaped structure are integrally moulded or formed by hermetically welding the box plates of respective surfaces.

7. The packaging box for an electronic device according to claim 1, wherein the input-output and control module is connected with the electronic device by means of a flexible flat cable.

8. The packaging box for an electronic device according to claim 1, wherein a movable support is further arranged at the bottom of the packaging box, the packaging box is placed on the movable support, and an inclination angle of a support surface of the movable support is adjustable.
